(19) United States
(12) Patent Application Publication
(10) Pub. No.: US 2008/0048226 A1
(43) Pub. Date: Feb. 28, 2008

(54) Direct cell via structures for ferroelectric random access memory devices and methods of fabricating such structures

(75) Inventors: Jang-Eun Heo, Seoul (KR); Suk-Hun Choi, Suwon-si (KR); Dong-Hyun Im, Seoul (KR); Dong-Chul Yoo, Seongnam-si (KR); Ik-Soo Kim, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/819,602

(22) Filed: Jun. 28, 2007

(30) Foreign Application Priority Data
Aug. 23, 2006 (KR) 10-2006-0080005

(51) Int. Cl. H01L 27/108; H01L 21/8242

(52) U.S. Cl. 257/295; 438/3; 257/E21.647; 257/E27.084

(57) ABSTRACT

Provided are FeRAM device constructions and fabrication methods that provide for the direct connection of metal patterns to ferroelectric capacitors. The FeRAM device constructions utilize a combination of one or more barrier layers incorporated in conductive plugs, barrier layers incorporated in primary conductive patterns or conductive patterns formed using one or more noble metals to suppress parametric drift associated with conventional FeRAM constructions.

### PRIORITY STATEMENT

This non-provisional application claims priority under 35 U.S.C. §119(a) on Korean Patent Application No. 10-2006-0080005, which was filed in the Korean Patent Office on Aug. 23, 2006, the contents of which is herein incorporated, in its entirety, by reference.

### BACKGROUND OF THE DISCLOSURE

### FIELD OF ENDEAVOR

The present disclosure relates generally to semiconductor devices and, more particularly, to ferroelectric memory cells and methods of fabricating such ferroelectric memory cells and devices that incorporate such ferroelectric cells.

### BACKGROUND OF THE INVENTION

Memory devices are used for storing data, program code, and/or other information in many electronic products including, for example, personal computers, embedded processor-based systems, digital cameras, video image processing circuits, cellular phones and MP3 players. The memory devices may be configured as dedicated memory integrated circuit (IC) devices or may comprise a region of a larger multifunction device such as a microprocessor or other IC device as on-chip memory.

Conventional DRAM devices are typically configured with distinct memory cell regions that include a regular array or grid of capacitors and the wiring and signaling transistors associated with the capacitors forming a plurality of memory cells and peripheral circuit regions that provide circuitry for other functions including, for example, input and output, electrostatic discharge (ESD) protection. A common configuration for the memory cells consists of a single capacitor and an associated transistor, that can be referred to as a “1T-1C” or “1TC” memory cell.

Data is stored in conventional DRAM cells by modifying the electrical charge in the capacitor, with the discharged state generally representing a “0” and the charged state generally representing a “1”. Writing data to a DRAM cell involves activating the associated control transistor and reducing the charge on the capacitor to a level where it will be recognized as a “0” or by increasing the charge on the capacitor to a level where it will be recognized as a “1”. Reading data from a DRAM cell is similar in that the associated control transistor is activated to connect the capacitor to a sense amplifier. If the capacitor was charged, the sense amplifier will detect a current pulse as the capacitor discharges and the memory cell will be read as a “1” and if the capacitor was already discharged, the sense amplifier will not detect such a pulse and the memory cell will be read as a “0”.

One disadvantage of conventional DRAM devices is that the reading operation is destructive in that the process of reading a memory cell in a charged state discharges the capacitor. As a result, the memory cell capacitor must be recharged in order for a subsequent reading operation to recognize the cell as a “1”. Further, even if the DRAM cell is not read, the charged capacitors must be periodically “refreshed” or recharged to ensure that the capacitor charge will be sufficient to be read as a “1” when connected to the sense amplifier. This “refresh” operation requires additional power and prevents conventional DRAM devices from retaining the stored data in the absence of a power supply and are, accordingly, designated as “volatile” memory devices.

The basic construction of ferroelectric random access memory (“FRAM” or “FeRAM”) cells are similar to those of DRAM cells, with the notable exception that the dielectric layer used in the DRAM capacitors is replaced with a thin film of a ferroelectric material, for example, lead zirconate titanate Pb(ZrₓTi₁₋ₓ)O₃ (PZT), in the FeRAM cells. Other ferroelectric materials include, for example, barium titanate BaTiO₃ (BTO), bismuth vanadate Bi₂VO_{5.5} (BVO), strontium bismuth tantalum, SrBi₂Ta₂O₉ (SBT), strontium bismuth tantalum nitride, SrₓBi_{2-y}(TaᵢNbⱼ)₂O_{9-z} (SBTN), strontium bismuth tantalum titanate, SrₓBi₃₋ₓTa_{2-y}Ti_{y}O₉ (SBTT), SrₓBi₃₋ₓTa_{2-y}Zr_{y}O₉ (SBTZ), and bismuth lanthanum titanate, Bi₄₋ₓLaₓTi₃O₁₂ (BLT). These example materials and other ferroelectric materials may be used singly or in combination to form the ferroelectric layer. When more than one ferroelectric material is used, the materials may be present as distinct layers achieved through sequential depositions or as composition gradients produced by altering the stoichiometry of the reactant gases continuously or in a stepwise fashion during the deposition process.

Unlike DRAM cells, however, the FeRAM cells do not store a rapidly depleted electrical charge on the capacitor electrodes. Conversely, in FeRAM cells application of a sufficient voltage across the ferroelectric film causes mobile atoms in the ferroelectric material to orient themselves in a similar fashion within the internal crystalline structure of the layer. These mobile atoms will remain in this orientation within the crystalline structure until reoriented by the application of a sufficient reverse voltage forces the mobile atoms to assume an alternate orientation. In FeRAM devices, therefore, the data written to the memory cell remains reflected in the relative orientation of the mobile atoms and does not require continual refreshing. FeRAM devices, therefore, can reduce power consumption dramatically relative to conventional DRAM devices of similar capacity.

Although the physical responses differ, a FeRAM device operates in a fashion similar to that of a DRAM device. Writing data to a FeRAM device is accomplished by applying a field of sufficient magnitude across the ferroelectric layer by applying appropriate voltage(s) to at least one of the electrodes arranged on opposite sides of the ferroelectric layer. This programming or writing voltage forces the mobile atoms within the crystal inside into the “up” or “down” orientation (depending on the polarity of the applied voltage), thereby storing a “1” or “0” respectively. Further, this induced orientation will be maintained even if power to the FeRAM device is not continuous.

Reading a FeRAM cell is, however, fundamentally different than reading a DRAM cell. Rather than connecting a capacitor to a sense amplifier to determine if the capacitor was charged, reading a FeRAM cell involves forcing the cell into a particular state, either a “0” or “1” and looking for a brief pulse of current associated with the reorientation of the mobile atoms in those instances in which the memory cell was in the opposite state. As with the DRAM cells, however, reading a FeRAM cell destroys the stored data and requires that the cells be re-written after reading, at least in those instances in which the state was changed during the reading operation.

An advantage of FeRAM devices over DRAM devices is, therefore, the operation of the memory devices during the interval between the read and write cycles. In DRAM devices, the charge deposited on the capacitor plates leaks across the insulating layer and the control transistor, and may drop below a consistently readable level fairly quickly. As noted above, in order to maintain the data within a DRAM device, every cell must be periodically read and then re-written, a process that requires a continuous supply of power and involves re-writing the entire memory array frequently, for example, every few milliseconds, whereby the majority of the power consumed by a DRAM device may be used simply for refresh processing.

In contrast, FeRAM devices only require power when actually reading or writing a memory cell. Accordingly, FeRAM devices can exhibit power consumption levels on the order of only about one percent or even less compared with the power consumption of a similarly sized DRAM device, making FeRAM devices particularly attractive for battery powered devices that will typically experience prolonged dormant periods, e.g., cell phones, digital cameras and MP3 players.

In addition to the 1T-1C (or 1TC) cell structure noted above, FeRAM devices may also be configured as two transistor-two capacitor (2T-2C or 2TC) structures. However, as suggested by the designations, those devices utilizing a 1TC structure utilize a unit cell will typically require less surface area than devices utilizing a 2TC structure fabricated under similar design rules. The 2TC configuration, therefore, tends to reduce the degree integration density that can be obtained. Accordingly, the 1TC unit cell structure is becoming more widely used to take advantage of the unit cell area reduction.

Reading operations on such FeRAM devices may be performed by applying a predetermined voltage pulse to the ferroelectric capacitor electrode in a unit cell associated with a transistor via an interconnection (for example, a plate line). In fabricating highly integrated ferroelectric memories, however, the capacitance of the ferroelectric capacitors can be several orders of magnitude greater than the conventional DRAM capacitors. Accordingly, the number of FeRAM cells that can be connected through a single plate line is generally limited to suppress a resistive-capacitive (RC) delay on the activating voltage pulses and maintain the operational speed of the device.

The capacitance C of a ferroelectric capacitor may be expressed by the following equation:

C=ε×A/d

wherein ε is the permittivity, A is the area of the electrode and d is the distance separating the electrodes, i.e., the thickness of the ferroelectric material layer. The electric field E that can be induced in the ferroelectric capacitor by an applied voltage V may be determined by the equation: E=V/d. Accordingly, in order to provide for low voltage operation and provide a large sensing margin, a smaller d, i.e., a thinner ferroelectric layer, will generally be preferred as long as the film quality remains sufficient to maintain acceptable processing and functional yields of such devices. For higher density devices, reducing the thickness of the lower electrode can reduce the footprint of the capacitor without reducing its capacity to store and maintain an adequate charge.

As shown in FIG. 1, ferroelectric materials exhibit a nonlinear relationship between the applied electric field (V) and the apparent stored charge (Q). Specifically, ferroelectric capacitors exhibit a characteristic hysteresis loop. The dielectric constant of a ferroelectric material is typically much higher than those of linear dielectrics because of the effects of semi-permanent electric dipoles formed in the crystal structure of the ferroelectric material. When an external electric field is applied across a dielectric, the dipoles tend to align themselves with the field direction, producing shifts in the positions of atoms and corresponding shifts in the distribution of electronic charge within the unit cells of the ferroelectric crystal structure as illustrated in FIGS. 2A and 2B which represent the “up” and “down” states respectively. After the charge is removed, the dipoles retain their polarization state. Typically binary “0”s and “1”s are stored as one of two possible electric polarizations in each data storage cell. For example, with reference to FIG. 1, a “1” would typically be encoded using the negative remnant polarization “−Pᵣ”, and a “0” is encoded using the positive remnant polarization “+Pᵣ”.

The reliability of FeRAM devices is a function, to some degree, of their resistance to parametric shift over their operational lifetime. One type of shifting is typically referred to a “imprinting” and is characterized by a lateral shift of the hysteresis curve illustrated in FIG. 1. For example, maintaining a remanent polarization for a long period of time can result in a shift of the ferroelectric hysteresis loop with respect to the applied voltage. This shift may contribute to two distinct failure modes in which the memory is rendered non-switchable if the voltage shift exceeds the writing voltage or wherein the sense amplifier may be unable to distinguish between the two different polarization states due to the loss of the remanent polarization.

The second type of shifting is generally referred to as fatigue and is exhibited as a “flattening” hysteresis curve reflecting the decreasing degree of polarization that can be achieved within the memory cell. The types of materials and configuration of those materials within the memory cell can improve the resistance to imprinting and/or fatigue as reflected in FIGS. 4A and 4B in which the selection of an appropriate electrode material, for example, an Ir/IrO₂ electrode construction rather than a Pt electrode can produce significant differences in the reliability of the resulting memory devices.

Operationally, a FeRAM is similar to DRAM. Writing is accomplished by applying a field across the ferroelectric layer by charging the plates on either side of it, forcing the atoms inside into the “up” or “down” orientation (depending on the polarity of the charge), thereby storing a “1” or “0”. Reading, however, is somewhat different than in DRAM. The transistor forces the cell into a particular state, say “0”. If the cell already held a “0”, nothing will happen in the output lines. If the cell held a “1”, the re-orientation of the atoms in the film will cause a brief pulse of current in the output as they push electrons out of the metal on the “down” side. The presence of this pulse means the cell held a “1”. Because this process overwrites the cell, reading FeRAM devices is a destructive process, and requires the cell to be re-written if it was changed.

One factor that slowed the adoption of FeRAM devices were their generally larger cell size (large cell size factor) relative to corresponding DRAM devices. Various efforts, therefore, have focused on improving the integration density of FeRAM devices through modified processes and structural changes to the functional elements. Two device configurations that have resulted from these efforts are the COB (capacitor over bit line) and CUB (capacitor under bit line) cell structures that can be utilized for reducing the cell size of the resulting FeRAM device.

Using a basic 1TC COB cell configuration and a 0.25 μm process, FeRAM cells exhibiting a 15 F² cell size factor have been produced successfully. Indeed, COB cell sizes in highly integrated devices may typically range from about 15 to about 25 F² with the actual capacitor area accounting for about 4 F² of the area. Additional reductions in the cell size factor approaching the theoretical 8 F² limit may be achieved by further developing three-dimensional ferroelectric capacitor technology including, for example, trench-type and box-type capacitors, improving the ferroelectric materials and/or improving fabrication processes. CUB configurations, however, typically exhibit much larger cell sizes when fabricated using corresponding processes, for example 70 to 90 F² with about 5 F² corresponding to the capacitor area. Not surprisingly, COB FeRAM configurations are preferred for more highly integrated devices. Additional process modifications including, for example, utilizing a single capacitor etch mask and an encapsulating barrier layer (EBL) may also improve the performance of the resulting FeRAM devices by reducing incidental damage suffered by the device structures.

### SUMMARY OF THE EXAMPLE EMBODIMENTS

Example embodiments include semiconductor devices comprising a semiconductor substrate; an array of transistors formed on the semiconductor substrate; a conductive line provided above the transistor array and electrically connected to a first source/drain region associated with a first transistor; a capacitor structure having a lower electrode, an upper electrode and a dielectric material provided between the lower and upper electrodes, wherein the capacitor structure is provided above a first reference plane defined by an upper surface of the bit line and electrically connected to a second source/drain region associated with the first transistor; a conductive plate provided above a second reference plane defined by an upper surface of the capacitor structure; and a conductive plug establishing a direct vertical electrical contact between the upper electrode and the conductive plate, wherein the conductive plug is a composite structure including both a primary conductor and a barrier material.

Example embodiments also include FeRAM devices comprising a semiconductor substrate; an array of transistors formed on the semiconductor substrate; a bit line provided above the transistor array and electrically connected to a source region associated with a first transistor; a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor; a conductive plate provided above a second reference plane defined by an upper surface of the ferroelectric structure; and a conductive plug establishing a direct vertical electrical contact between the upper electrode and the conductive plate, wherein the conductive plug is a composite structure including both a primary conductor and a barrier material.

Example embodiments also include FeRAM devices in which the conductive plug includes a lower layer of a barrier material selected from a group consisting of SrRuO₃ (SRO) and CaRuO₃ and having a thickness T_{b}; and an upper layer of the primary conductor. The primary conductor may be selected from a group consisting of refractory metals including, for example, tungsten (W), titanium (Ti) and tantalum (Ta), as well as mixtures and alloys thereof, and having a thickness Tₚ, wherein the expression Tₚ≧T_{b} is satisfied and may include Tₚ:T_{b} thickness ratios greater than 4.

Other example embodiments include those in which the conductive plug further comprises an upper layer of a barrier material selected from a group consisting of SrRuO₃ (SRO) and CaRuO₃ (CRO) having a thickness Tᵤ and a lower layer of the primary conductor having a thickness Tₚ, wherein the expression Tₚ≧T_{b} is satisfied and may include ratios greater than 4.

Example embodiments of FeRAM devices further include those in which the barrier material forms an outer layer along side surfaces and a bottom surface of the conductive plug and surrounds a core formed from the primary conductor. The barrier material may be selected from a group consisting of SrRuO₃ (SRO) and CaRuO₃ and has a thickness T_{b}. The core of the primary conductor has an average diameter T_{w}, wherein the expression T_{w}≧2T_{b} is satisfied.

Additional example embodiments include FeRAM devices comprising a semiconductor substrate; an array of transistors formed on the semiconductor substrate; a bit line provided above the transistor array and electrically connected to a source region associated with a first transistor; a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor; a composite conductive plate including a bottom layer of a barrier material and an upper layer of a primary conductor provided above a second reference plane defined by an upper surface of the ferroelectric structure; and a conductive plug establishing a direct vertical electrical contact between the upper electrode and the conductive plate. The barrier layer material may be selected from a group consisting of SrRuO₃ (SRO) and CaRuO₃ (CRO) and has a thickness T_{b} and the upper layer of the primary conductor has a thickness Tₚ.

Additional example embodiments include FeRAM devices comprising a semiconductor substrate; an array of transistors formed on the semiconductor substrate; a bit line provided above the transistor array and electrically connected to a source region associated with a first transistor; a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor; a conductive plate substantially free of both copper (Cu) and aluminum (Al) provided above a second reference plane defined by an upper surface of the ferroelectric structure; and a conductive plug establishing a direct vertical electrical contact between the upper electrode and the conductive plate. In these example embodiments, the conductive plate may include a primary metal selected from a group consisting of Pt, Ru, Ir, Rh, Os, Pd, Sr and alloys thereof and may further include nitrides oxides and oxynitrides of the primary metal(s). In these example embodiments, the upper electrode may include a top layer of iridium (Ir) formed directly on a layer of iridium oxide (IrO₂).

The construction of these example embodiments may be used in producing FeRAM devices that are able to maintain at least 90% of their original polarization value (Pr₀) for at least 10¹⁰ programming cycles. Other example embodiments may utilize an upper electrode including a top layer of a metal formed directly on a layer of an oxide of that metal, wherein the metal is selected from a group consisting of iridium (Ir), ruthenium (Ru), ruthenium/strontium alloys and ruthenium/calcium alloys.

Example embodiments of manufacturing methods for forming such FeRAM devices may comprise forming an array of transistors in a semiconductor substrate; forming a first interlayer insulating layer over the transistors; forming a bit line in the interlayer insulating layer above the transistor array and electrically connected to a source region associated with a first transistor; forming a second interlayer insulating layer; forming a ferroelectric structure on the second interlayer insulating layer above the bit line, wherein the ferroelectric structure includes a lower electrode, an upper electrode and a ferroelectric material provided between the lower and upper electrodes and further wherein the ferroelectric structure is electrically connected to a drain region associated with the first transistor; forming a third interlayer insulating layer; forming conductive plugs through the third interlayer insulating layer to contact the upper electrode; and forming a conductive plate on the third insulating layer, wherein the conductive plate is electrically connected to the upper electrode through the conductive plug. wherein the conductive plug is a composite structure including both a primary conductor and a barrier material.

Forming the conductive plug in such example embodiments may further include forming openings through the third interlayer insulating layer to expose portions of an upper surface of the upper electrode; depositing a layer of the primary conductor to a thickness sufficient to fill the openings; removing an upper portion of the primary conductor to expose an upper surface of the third interlayer insulating layer and form a planarized surface, thereby forming a primary conductor pattern of plugs; removing an upper portion of the primary conductor pattern to form recessed regions; depositing a layer of the barrier material sufficient to fill the recessed regions; and removing an upper portion of the barrier material to expose the upper surface of the third interlayer insulating layer to form the composite conductive plugs. Forming the conductive plugs may further comprise forming openings through the third interlayer insulating layer to expose portions of an upper surface of the upper electrode; depositing a layer of the barrier material sufficient to fill the recessed regions; and removing an upper portion of the barrier material to expose the upper surface of the third interlayer insulating layer to form a planarized surface and to form a barrier material pattern; removing an upper portion of the barrier material pattern to form recessed regions; depositing a layer of the primary conductor to a thickness sufficient to fill the recessed regions; removing an upper portion of the primary conductor to expose an upper surface of the third interlayer insulating layer and form a planarized surface, thereby forming the composite conductive plugs. Forming the conductive plugs may also comprise forming openings through the third interlayer insulating layer to expose portions of an upper surface of the upper electrode; depositing a conformal layer of the barrier material sufficient to form a layer of barrier material on surfaces exposed in the openings to form reduced diameter openings; and depositing a layer of the primary conductor to a thickness sufficient to fill the reduced diameter openings; removing upper portions of the barrier material and the primary conductor to expose an upper surface of the third interlayer insulating layer and form a planarized surface, thereby forming the composite conductive plugs.

Other example embodiments of forming such FeRAM devices may comprise forming an array of transistors in a semiconductor substrate; forming a first interlayer insulating layer over the transistors; forming a bit line in the interlayer insulating layer above the transistor array and electrically connected to a source region associated with a first transistor; forming a second interlayer insulating layer; forming a ferroelectric structure on the second interlayer insulating layer above the bit line, wherein the ferroelectric structure includes a lower electrode, an upper electrode and a ferroelectric material provided between the lower and upper electrodes and further wherein the ferroelectric structure is electrically connected to a drain region associated with the first transistor; forming a third interlayer insulating layer; forming conductive plugs through the third interlayer insulating layer to contact the upper electrode; forming a barrier layer on the surface of the third interlayer insulating layer; forming a primary conductor layer on the surface of the barrier layer; and forming a plate pattern and etching the primary conductor layer and the barrier layer to form a conductive plate pattern on the third interlayer insulating layer, wherein the conductive plate is directly connected to the upper electrode through the barrier material and the conductive plug.

### BRIEF DESCRIPTION OF THE DRAWINGS

Example embodiments described below will be more clearly understood when the detailed description is considered in conjunction with the accompanying drawings, in which:

FIG. 1 illustrates a basic FeRAM hysteresis curve reflecting the degree of polarization on the y-axis and the value of the applied voltage on the x-axis;

FIGS. 2A and 2B illustrate the movement of the body-centered atom in a ferroelectric structure, specifically a Perovskite structure which is an octahedral 1 group crystal having a basic formula of ABO₃;

FIGS. 3A to 3C illustrate more complex ferroelectric structures including octahedral 2 group, octahedral 3 group and octahedral 4 group structures respectively;

FIGS. 4A and 4B illustrate the improved fatigue resistance exhibited by an Ir/IrO₂ electrode configuration relative to a Pt electrode configuration;

FIG. 5 illustrates a first example embodiment of a FeRAM construction;

FIG. 6 illustrates another example embodiment of a FeRAM construction;

FIG. 7 illustrates another example embodiment of a FeRAM construction;

FIG. 8 illustrates another example embodiment of a FeRAM construction;

FIG. 9 illustrates another example embodiment of a FeRAM construction;

FIGS. 10-15 illustrate a first example embodiment of a FeRAM fabrication process; and

FIGS. 16-19 illustrate other example embodiments of a FeRAM fabrication process.

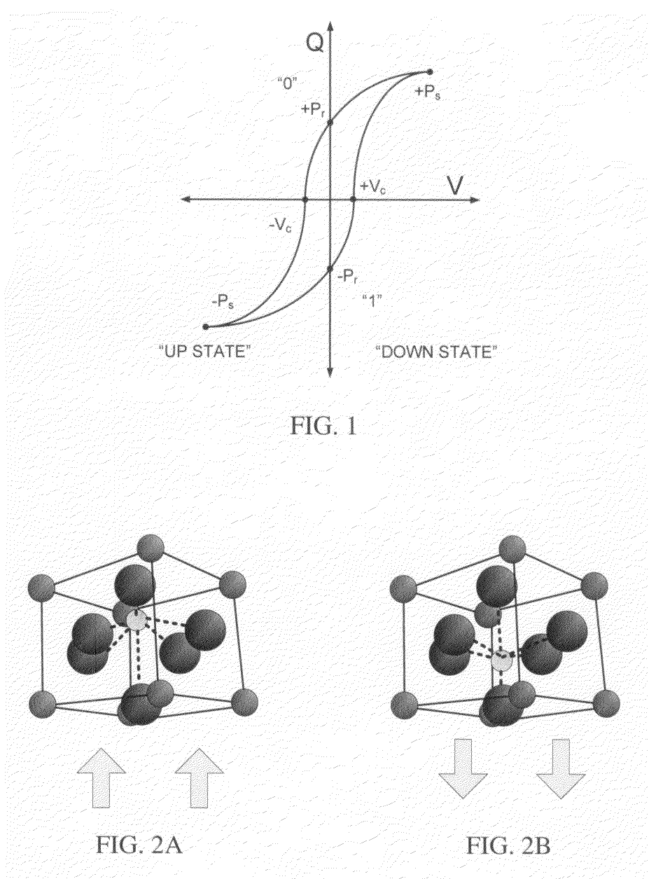

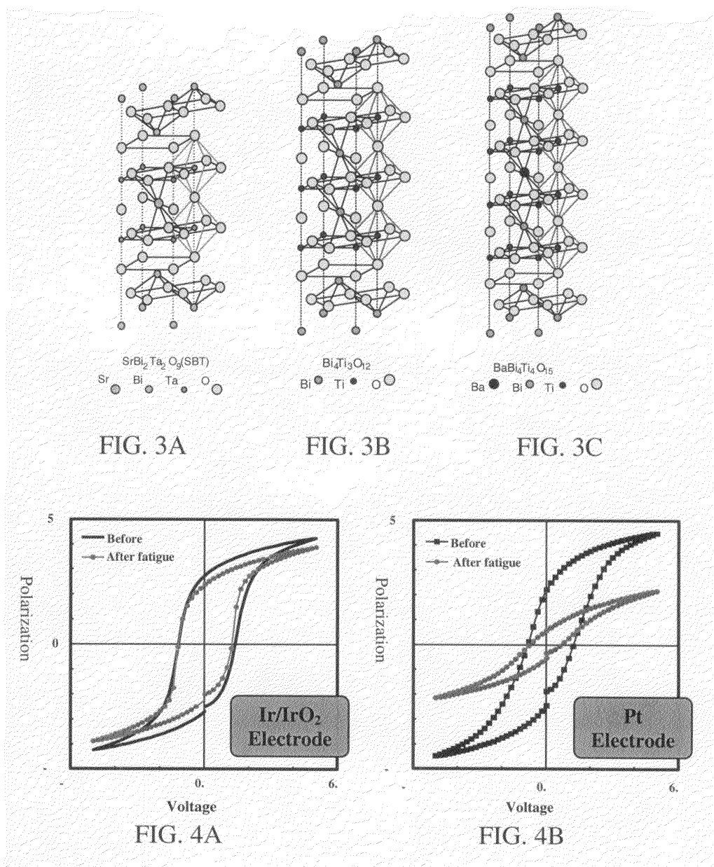

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the full scope of the disclosure to those skilled in the art. Like numbers refer to like elements throughout.

Those skilled in the art will also understand that when an element such as a layer, region or substrate is referred to as being “on” another element, it can be directly on the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

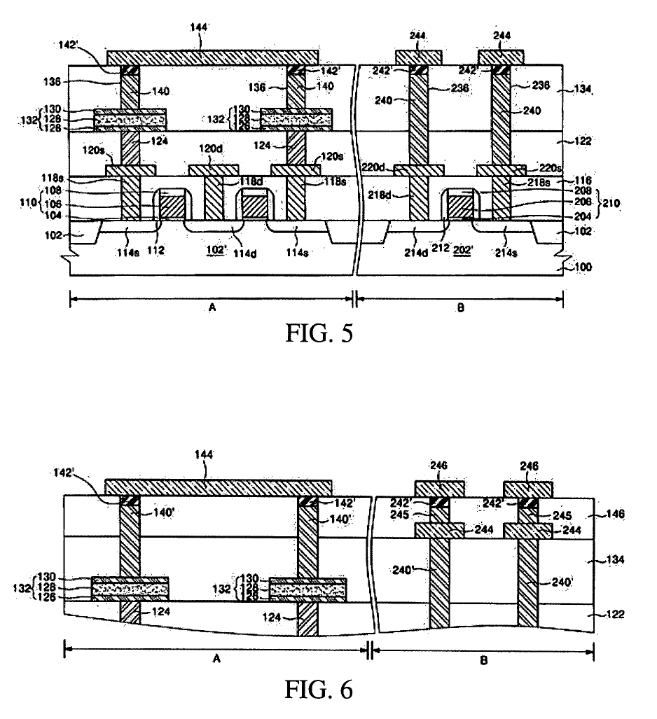

As illustrated in FIG. 5, a first example embodiment of an FeRAM construction includes both a memory or cell region A and a peripheral or logic circuitry region B that have been combined, for convenience, in a single view. As will be appreciated by those skilled in the art, however, these two regions may be widely separated on an actual device. As illustrated in FIG. 5, the substrate 100 has been separated into active regions 102′, 202′ by a series of shallow trench isolation (STI) structures 102.

A series of doped regions including source 114s and common drain 114d regions are formed in the upper portion of the active regions. Gate electrode structures 110, 210, including a gate dielectric 104, 204, a first conductive pattern 106, 206, and a second conductive pattern 108, 208 and insulating spacers 112, 212 formed on the sidewalls of the gate electrode structures 110, 210. An interlayer dielectric layer 116 is then formed over the existing structures and a series of contact openings are formed to expose portions of the source/drain (sometimes abbreviated as S/D) regions. The interlayer dielectric layer 116 may also be subjected to one or more planarizing processes including, for example, blanket etches (etchback) and chemical mechanical polishing (CMP) to provide a substantially planar surface suitable for additional processing. A series of conductive plugs 118s, 118d, 218d, 218s (collectively 118, 218 unless otherwise designated) are then formed through the contact openings to provide an electrical path to each of the S/D regions. Additional conductive patterns 120s, 120d and 220s, 220d (collectively 120, 220 unless otherwise indicated), are then formed on the insulating layer 116 in order to establish electrical contact to the corresponding conductive plugs 118, 218 respectively. As illustrated in FIG. 5, the conductive pattern 120d may also be referred to as the bitline (BL).

An interlayer dielectric layer 122 may then be formed over the existing structures and a series of contact openings are formed to expose portions of the underlying conductive patterns 120, 220. The interlayer dielectric layer 122 may also be subjected to one or more planarizing processes, as noted supra, to provide a substantially planar surface suitable for additional processing. A series of conductive plugs 124 are then formed through the contact openings to provide an electrical path to the conductive patterns 120.

In the cell region A, a ferroelectric capacitor pattern 132 is formed by depositing a lower or bottom electrode layer on the surface of the interlayer dielectric layer 122 and the conductive plugs 124 formed through the insulating layer. A ferroelectric material layer is then formed on the exposed surfaces of the insulating layer 122 and the conductive plugs and finally, a top or upper electrode layer is formed on the exposed surface of the ferromagnetic layer. This stack of materials was then patterned and etched to form discrete ferroelectric capacitors 132 comprising a bottom electrode pattern 126, a ferromagnetic material pattern 128 and an upper electrode pattern 130 on the surface of the second insulating layer 122.

A third interlayer dielectric layer 134 is then formed on the capacitors 132 and the exposed surface of the second interlayer dielectric layer 122. Contact openings 136, 236 are then formed in the third insulating layer 134 to expose portions of the upper electrode pattern 130 in the cell region A and the conductive patterns 220 in the peripheral region B. These contact openings 136, 236 are then filled with a first conductive material 140, 240, typically tungsten (W) or another refractory metal, combination of metals or alloys thereof.

An upper portion of the first conductive material is then removed and a second conductive material 142′, 242′ suitable for use as a barrier layer is used to complete the conductive paths between the upper electrode patterns 130 and conductive patterns 220 and the upper surface of the third insulating layer 134. As will be appreciated, depending on the relative thicknesses and deposition techniques utilized, one or more planarization operations may be utilized to achieve the structure illustrated in FIG. 5 and provide a substantially planar surface suitable for additional processing.

A conductive layer is then formed on the upper surface of the third insulating layer 134 and the exposed surfaces of the second conductive material 142′, 242′. This conductive layer is then patterned and etched to obtain a metal plate structure 144 in the cell region A and a METAL 1 pattern 244 in the peripheral region.

An alternative construction is illustrated in FIG. 6 in which the formation of the contact openings in the cell region is delayed until after the conductive plugs 240′ are formed in the peripheral region and the METAL 1 pattern 244 has been provided for connecting the conductive plugs. A fourth intermetallic dielectric layer 146 is then formed on the METAL 1 pattern 244 and openings are formed through the insulating layers 146, 134 to expose portions of the METAL 1 pattern 244 in the peripheral region and the upper electrode pattern 130 in the cell region.

These contact openings are then filled with a first conductive material 140′, 240′, typically tungsten (W) or another refractory metal, combination of metals or alloys thereof. An upper portion of the first conductive material is then removed and a second conductive material 142′, 242′ suitable for use as a barrier layer is used to complete the conductive paths between the upper electrode patterns 130 and METAL 1 pattern 244 and the upper surface of the fourth intermetallic dielectric layer 146. As will be appreciated, depending on the relative thicknesses and deposition techniques utilized, one or more planarization operations may be utilized to achieve the structure illustrated in FIG. 6 and provide a substantially planar surface suitable for additional processing.

A conductive layer is then formed on the upper surface of the fourth intermetallic dielectric layer 146 and the exposed surfaces of the second conductive material 142′, 242′ filling the upper portion of the contact openings in the cell region and the via openings in the peripheral region. This conductive layer is then patterned and etched to obtain a metal plate structure 144 in the cell region A and a METAL 2 pattern 246 in the peripheral region.

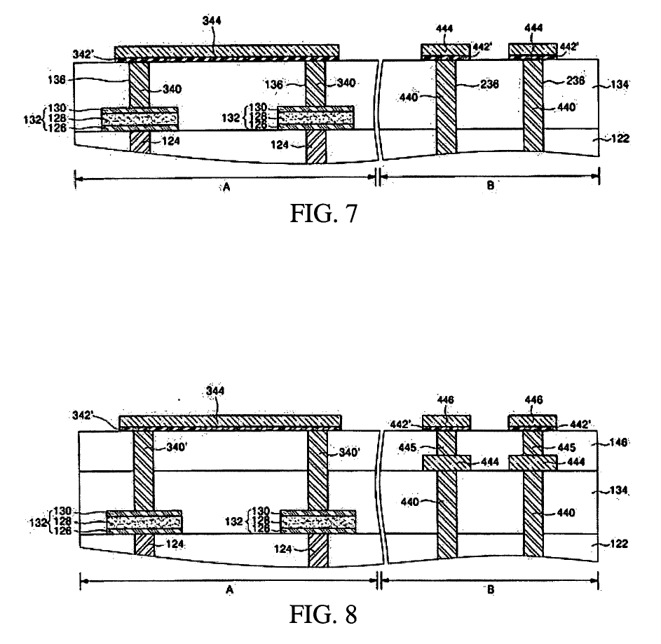

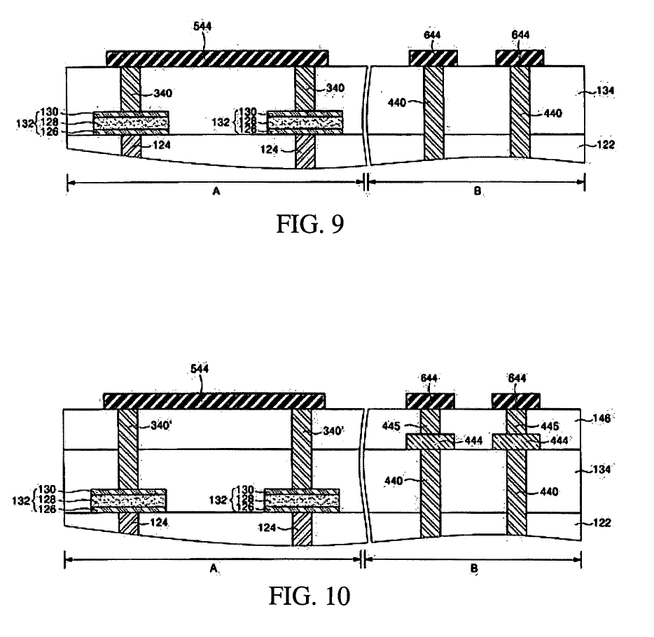

As illustrated in FIGS. 7 and 8, the FeRAM structures described above and the associated fabrication process may be modified with respect to the formation of the barrier layer regions 142′, 242′ provided in the contact and/or via openings of the FeRAM structures illustrated in FIGS. 5 and 6. In particular, as illustrated in FIG. 7, the barrier layer regions 142′, 242′ may be omitted from the upper portion of the contact and/or via plug structures and may instead be provided as a barrier layer pattern 342′, 442′ underlying the metal plate pattern 344 in the cell region and the METAL 1 pattern 444 in the peripheral region. Similarly, as illustrated in FIG. 8, the barrier layer regions 142′, 242′ may be omitted from the upper portion of the contact and/or via plug structures and may instead be provided as a barrier layer pattern 342′, 442′ underlying the metal plate pattern 344 in the cell region and the METAL 2 pattern 444 in the peripheral region.

As illustrated in FIGS. 11-15, a first example embodiment of an FeRAM fabrication process includes both a memory or cell region A and a peripheral or logic circuitry region B that have been combined, for convenience, in a single view. As will be appreciated by those skilled in the art, however, these two regions may be widely separated on an actual device.

As illustrated in FIG. 11, the substrate 100 has been separated into active regions 102′, 202′ by a series of shallow trench isolation (STI) structures 102. A series of doped regions including source 114s and common drain 114d regions are formed in the upper portion of the active regions. Gate electrode structures 110, 210, including a gate dielectric 104, 204, a first conductive pattern 106, 206, and a second conductive pattern 108, 208 and insulating spacers 112, 212 formed on the sidewalls of the gate electrode structures 110, 210. An interlayer dielectric layer 116 is then formed over the existing structures and a series of contact openings are formed to expose portions of the source/drain (sometimes abbreviated as S/D) regions. The interlayer dielectric layer 116 may also be subjected to one or more planarizing processes including, for example, blanket etches (etchback) and chemical mechanical polishing (CMP) to provide a substantially planar surface suitable for additional processing. A series of conductive plugs 118s, 118d, 218d, 218s (collectively 118, 218 unless otherwise designated) are then formed through the contact openings to provide an electrical path to each of the S/D regions. Additional conductive patterns 120s, 120d and 220s, 220d (collectively 120, 220 unless otherwise indicated), are then formed on the insulating layer 116 in order to establish electrical contact to the corresponding conductive plugs 118, 218 respectively. As illustrated in FIG. 5, the conductive pattern 120d may also be referred to as the bitline (BL).

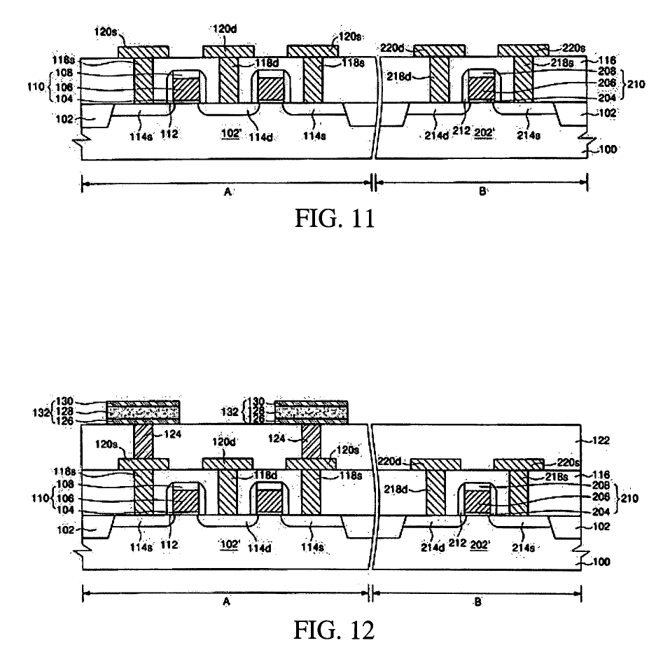

As illustrated in FIG. 12, an interlayer dielectric layer 122 may then be formed over the existing structures and a series of contact openings are formed to expose portions of the underlying conductive patterns 120, 220. The interlayer dielectric layer 122 may also be subjected to one or more planarizing processes, as noted supra, to provide a substantially planar surface suitable for additional processing. A series of conductive plugs 124 are then formed through the contact openings to provide an electrical path to the conductive patterns 120.

In the cell region A, a ferroelectric capacitor pattern 132 is formed by depositing a lower or bottom electrode layer (not shown) on the surface of the interlayer dielectric layer 122 and the conductive plugs 124 formed through the insulating layer. A ferroelectric material layer (not shown) is then formed on the exposed surfaces of the insulating layer 122 and the conductive plugs and finally, a top or upper electrode layer (not shown) is formed on the exposed surface of the ferromagnetic layer. This stack of materials is then patterned using, for example a photoresist pattern or a hard mask pattern (not shown) and etched to form discrete ferroelectric capacitors 132 comprising a bottom electrode pattern 126, a ferromagnetic material pattern 128 and an upper electrode pattern 130 on the surface of the second insulating layer 122.

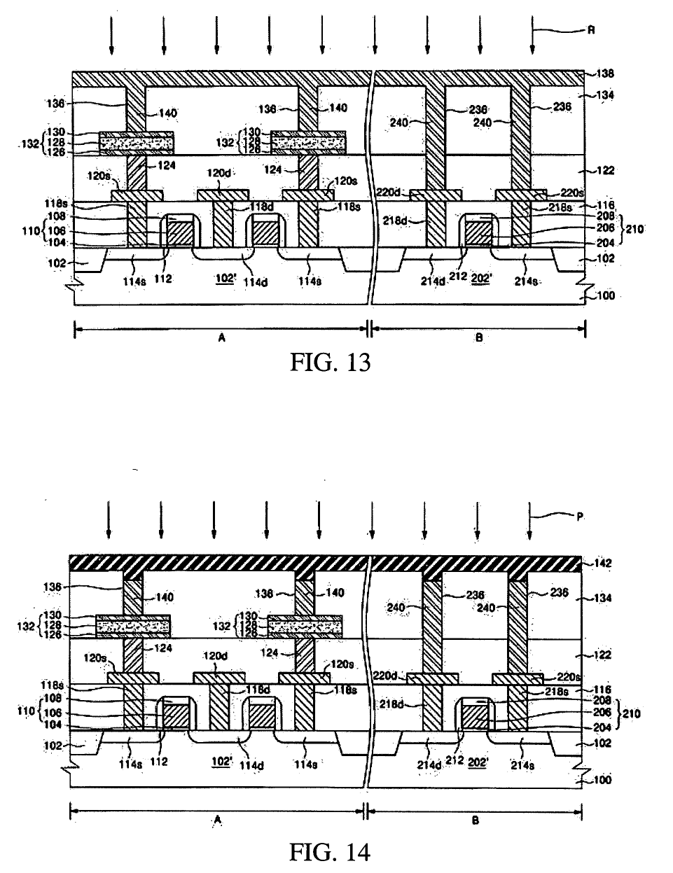

As illustrated in FIG. 13, a third interlayer dielectric layer 134 is then formed on the capacitors 132 and the exposed surface of the second interlayer dielectric layer 122. Contact openings 136, 236 are then formed in the third insulating layer 134 to expose portions of the upper electrode pattern 130 in the cell region A and the conductive patterns 220 in the peripheral region B. These contact openings 136, 236 are then filled by depositing a layer of a first conductive material, typically tungsten (W) or another refractory metal, combination of metals or alloys thereof. The upper portion of this first conductive layer is then removed, typically through a combination of CMP and etching to expose an upper surface of the second interlayer dielectric layer 134 and remove a portion of the first conductive material from the contact openings to form a plurality of recessed regions (not shown).

As illustrated in FIG. 14, an upper portion of the first conductive material layer 138 is then removed and a layer of a second conductive material 142 suitable for use as a barrier layer is deposited on the exposed surface of the second interlayer dielectric layer 134 and filling the upper portion of the contact openings, i.e., the recessed regions. As will be appreciated, depending on the relative thicknesses and deposition techniques utilized, one or more planarization operations may be utilized to achieve the structure illustrated in FIG. 14 and provide a substantially planar surface suitable for additional processing.

As illustrated in FIG. 15, an upper portion of the second conductive material layer 142 is then removed by, for example, a suitable CMP process, etchback process or a combination thereof, to expose an upper surface of the second interlayer dielectric layer 134, thereby providing a pattern of the second conductive material 142′, 242′ in the upper portions of the contact openings and a substantially planar surface suitable for additional processing.

A conductive layer is then formed on the upper surface of the third insulating layer 134 and the exposed surfaces of the second conductive material 142′, 242′. This conductive layer is then patterned and etched to obtain a metal plate structure 144 in the cell region A and a METAL 1 pattern 244 in the peripheral region.

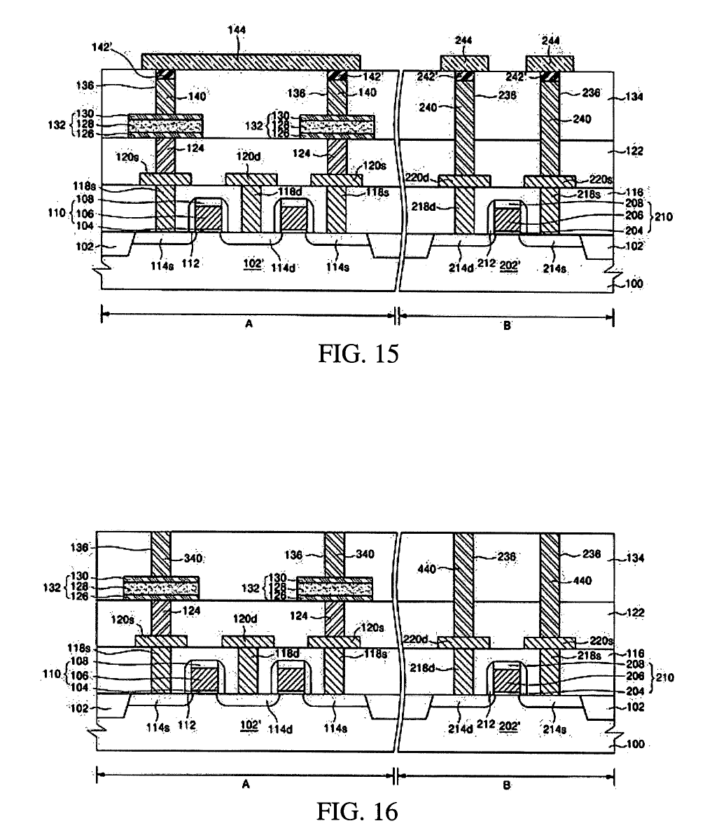

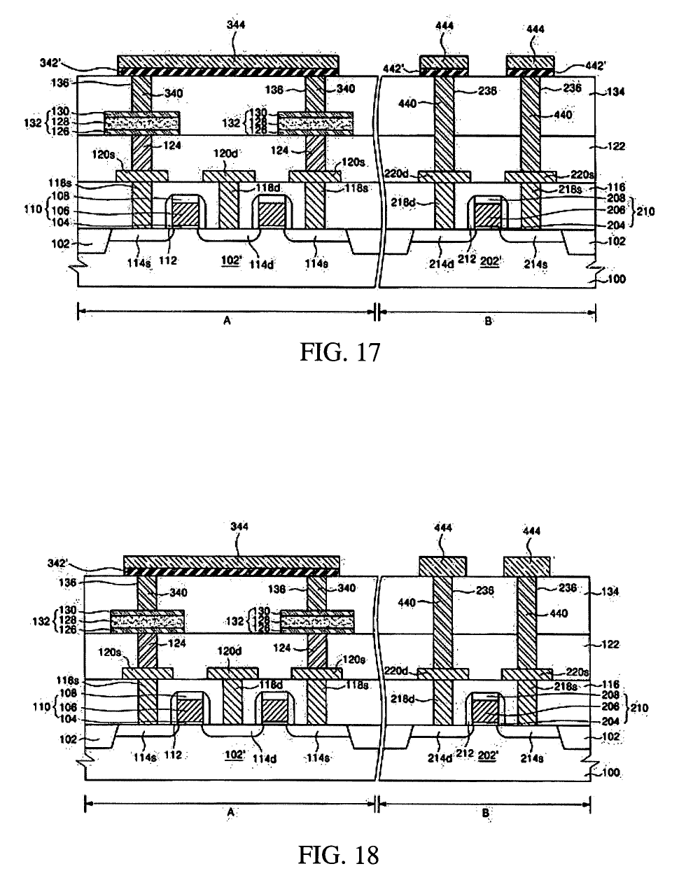

An alternative example embodiment of a fabrication method is illustrated in FIGS. 16-18. As illustrated in FIG. 16, the initial stages of the fabrication method may parallel those discussed supra with respect to the formation of the illustrated FeRAM structure. As reflected in FIG. 16, however, less of the upper portion of this first conductive layer is removed by, for example, a suitable CMP process, whereby a sufficient portion of the first conductive layer 138 remains to fill the contact openings with a pattern of conductive plugs. A layer of a barrier material (not shown) is then deposited on the upper surface of the second interlayer dielectric layer 134 and the contact plugs. A second conductive layer (not shown) is then formed on the barrier layer material to form a composite or stacked conductive layer (not shown). This composite layer is then patterned and etched to obtain a metal plate structure 342′, 344 in the cell region A and the METAL 1 pattern 442′, 444 in the peripheral region as illustrated in FIG. 17.

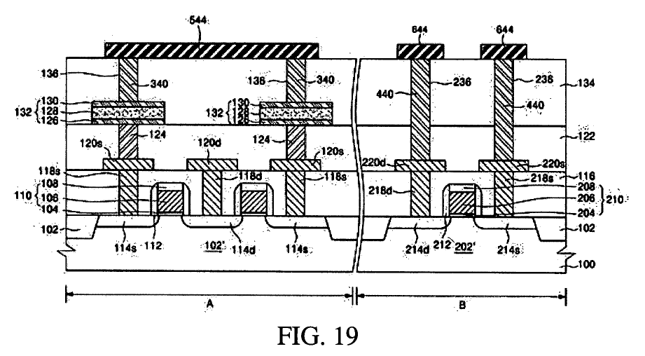

As will be appreciated by those skilled in the art, the structural elements described above may be adapted to provide additional example embodiments including, for example, the FeRAM construction illustrated in FIG. 18 wherein the conductive structures in the memory cell and peripheral regions are not identical. As illustrated in FIG. 18, the advantages associated with the use of the barrier material layer 342′ in forming the metal plate conductor in the cell region need not be duplicated in the peripheral region. Corresponding modifications to the fabrication method could include, for example, a patterning and etching sequence in which the barrier material layer is protected only in the cell region and, optionally, portions of the peripheral region in which the barrier layer may provide some advantage.

As will also be appreciated by those skilled in the art, the structural elements described above may be adapted to provide additional example embodiments including, for example, the FeRAM construction illustrated in FIG. 19 wherein the conductive structures in the memory cell and peripheral regions are identical but the barrier layer portions have been omitted from both the upper regions of the conductive plugs provided in the contact and/or via openings but also from beneath the plate and METAL 1 patterns in favor of a noble metal pattern.

For the purposes of the FeRAM structures and methods of fabrication detailed above, it is expected that the electrodes will be fabricated from one or more materials selected from a group consisting of Ir, IrRu alloys, IrTi alloys, lrO₂, Pt, SrRuO₃ (SRO), CaRuO₃ (CRO), as well as combinations and mixtures thereof including, for example, Ir/IrO₂. As will be appreciated by those skilled in the art, these materials may be deposited using a variety of techniques including, for example, sputtering, CVD, ALD, and each material and combination of materials exhibits both advantages and disadvantages with respect to their resistance to diffusion of oxygen, hydrogen, metals, for example, Pb, thermal stability, fatigue endurance when associated with an appropriate ferroelectric, growth characteristics, leakage and processing characteristics.

Similarly, the use of one or more of the electrode/barrier materials and/or noble metal conductors will tend to present one or more integration issues with regard to conventional silicon fabrication techniques. Such issues may include, for example, sensitivity to oxidation, hydrogen damage to the ferroelectric material, for example, PZT, interface barriers. Those skilled in the art, however, will appreciate that such issues may be reduced or removed by techniques and methods including, for example, the use of antioxidation barrier materials (TiAlN or TaSiN for example), encapsulating barrier layers (EBL) formed from, for example, Al₂O₃ (sapphire) and/or TiO₂, reduced hydrogen materials and processing, reduced thermal budget processing and/or damage curing.

For the purposes of this disclosure, those metals that may be used in forming the noble metal conductor patterns include Pt, Ru, Ir, Rh, Os, Pd and Sr as well as combinations and alloys thereof. In some instances, the oxides, nitride and/or oxynitrides of these noble metals may be used in combination with the metal(s) for improving resistance to parametric shifts over the operational life of the resulting FeRAM devices. The barrier layer may be formed from, for example, SRO, CRO, a combination thereof or any other combination of materials that provide a suitable combination of barrier properties and processability.

As will be appreciated by those skilled in the art from the description above and the corresponding Figures, example embodiments include methods of fabricating trench isolation structures that may provide reduced leakage, improved process yield and/or improved reliability by reducing the occurrence of voids in trench isolation structures, particularly those having higher aspect ratios and/or reducing the likelihood of overetch damage in the peripheral regions during E/B processes.

As will be appreciated by those skilled in the art, other combinations of insulating, semiconducting and conducting materials may be utilized in practicing methods in accord with the example embodiments detailed above. Such alternative combinations of materials, however, should be selected to provide appropriate combinations of properties whereby at least some of the advantages of the example embodiments are realized and should include, therefore, the elimination of conventional ATE structures in favor of direct connection of the metal patterns to the ferroelectric capacitors and the use of barrier layer materials and/or conductive patterns of noble metals, thereby improving the reliability and manufacturability of the resulting FeRAM devices.

Accordingly, although certain example embodiments have been disclosed for illustrative purposes, those skilled in the art will appreciate that various conventional modifications, additions and substitutions to the particular materials and techniques are possible, without departing from the scope and spirit of the disclosure.

1. A semiconductor device comprising:
a semiconductor substrate;
an array of transistors formed on the semiconductor substrate;
a conductive line provided above the transistor array and electrically connected to a first source/drain region associated with a first transistor;
a capacitor structure having a lower electrode, an upper electrode and a dielectric material provided between the lower and upper electrodes, wherein the capacitor structure is provided above a first reference plane defined by an upper surface of the bit line and electrically connected to a second source/drain region associated with the first transistor;
a conductive plate provided above a second reference plane defined by an upper surface of the capacitor structure; and
a conductive plug establishing a direct vertical electrical contact between the upper electrode and the conductive plate, wherein the conductive plug is a composite structure including both a primary conductor and a barrier material.

2. A FeRAM device comprising:
a semiconductor substrate;
an array of transistors formed on the semiconductor substrate;
a bit line provided above the transistor array and electrically connected to a drain region associated with a first transistor;
a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor;
a conductive plate provided above a second reference plane defined by an upper surface of the ferroelectric structure; and
a conductive plug establishing a direct vertical electrical contact between the upper electrode and the conductive plate, wherein the conductive plug is a composite structure including both a primary conductor and a barrier material.

3. The FeRAM device according to claim 2, wherein the conductive plug further comprises:
a lower layer of a barrier material selected from a group consisting of SrRuO₃ (SRO) and CaRuO₃ having a thickness Tb; and
an upper layer of the primary conductor.

4. The FeRAM device according to claim 3, wherein:
the primary conductor is selected from a group consisting of refractory metals, combinations and alloys thereof and has a thickness Tₚ, wherein the expression Tₚ≧T_{b} is satisfied.

5. The FeRAM device according to claim 4, wherein:
the thickness Tₚ and the thickness T_{b} define a thickness ratio Tₚ:T_{b} of at least 4.

6. The FeRAM device according to claim 2, wherein the conductive plug further comprises:
an upper layer of a barrier material selected from a group consisting of SrRuO₃ (SRO) and CaRuO₃ (CRO) having a thickness T_{b}.

7. The FeRAM device according to claim 6, wherein the conductive plug further comprises:
a lower layer of the primary conductor having a thickness Tₚ, wherein the expression Tₚ≧T_{b} is satisfied.

8. The FeRAM device according to claim 6, wherein:
the primary conductor is selected from a group consisting of refractory metals, combinations and alloys thereof.

9. The FeRAM device according to claim 6, wherein:
the thickness Tₚ and the thickness T_{b} define a thickness ratio Tₚ:T_{b} of at least 4.

10. The FeRAM device according to claim 2, wherein:
the barrier material forms an outer layer along side surfaces and a bottom surface of the conductive plug and surrounds a core formed from the primary conductor.

11. The FeRAM device according to claim 10, wherein:
the barrier material is selected from a group consisting of SrRuO₃ (SRO) and CaRuO₃ and has a thickness T_{b}; and
the core of the primary conductor has an average diameter T_{w}, wherein the expression T_{w}≧2T_{b} is satisfied.

12. A FeRAM device comprising:
a semiconductor substrate;
an array of transistors formed on the semiconductor substrate;
a bit line provided above the transistor array and electrically connected to a drain region associated with a first transistor;
a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor;
a composite conductive plate including a bottom layer of a barrier material and an upper layer of a primary conductor provided above a second reference plane defined by an upper surface of the ferroelectric structure; and
a conductive plug establishing a direct vertical electrical contact between the upper electrode and the conductive plate.

13. The FeRAM device according to claim 12, wherein:
the barrier material is selected from a group consisting of SrRuO₃ (SRO) and CaRuO₃ (CRO) and has a thickness T_{b}; and
the upper layer of the primary conductor has a thickness Tₚ.

14. A FeRAM device comprising:
a semiconductor substrate;
an array of transistors formed on the semiconductor substrate;
a bit line provided above the transistor array and electrically connected to a source region associated with a first transistor;
a ferroelectric structure having a lower electrode, an upper electrode and a ferroelectric material provided between the lower and upper electrodes, wherein the ferroelectric structure is provided above a first reference plane defined by an upper surface of the bit line and electrically connected to a drain region associated with the first transistor;
a conductive plate substantially free of both copper (Cu) and aluminum (Al) provided above a second reference plane defined by an upper surface of the ferroelectric structure; and
a conductive plug establishing a direct vertical electrical contact between the upper electrode and the conductive plate.

15. The FeRAM device according to claim 14, wherein:
the conductive plate includes a primary metal selected from a group consisting of Pt, Ru, Ir, Rh, Os, Pd, Sr, mixtures, combinations and alloys thereof.

16. The FeRAM device according to claim 15, wherein:
the conductive plate includes a nitride or an oxide of the primary metal.

17. The FeRAM device according to claim 2, wherein:
the upper electrode includes a top layer of iridium (Ir) formed directly on a layer of iridium oxide (IrO₂).

18. The FeRAM device according to claim 17, wherein:
at least 90% of an original polarization value Pr₀ is maintained for at least 10¹⁰ programming cycles.

19. The FeRAM device according to claim 2, wherein:
the upper electrode includes a top layer of a metal formed directly on a layer of an oxide of the metal, wherein the metal is selected from a group consisting of iridium (Ir), ruthenium (Ru), ruthenium/strontium alloys and ruthenium/calcium alloys.

20. A method of forming a FeRAM device comprising:
forming an array of transistors in a semiconductor substrate;
forming a first interlayer insulating layer over the transistors;
forming a bit line in the interlayer insulating layer above the transistor array and electrically connected to a source region associated with a first transistor;
forming a second interlayer insulating layer;
forming a ferroelectric structure on the second interlayer insulating layer above the bit line, wherein the ferroelectric structure includes a lower electrode, an upper electrode and a ferroelectric material provided between the lower and upper electrodes and further wherein the ferroelectric structure is electrically connected to a drain region associated with the first transistor;
forming a third interlayer insulating layer;
forming conductive plugs through the third interlayer insulating layer to contact the upper electrode; and
forming a conductive plate on the third insulating layer, wherein the conductive plate is electrically connected to the upper electrode through the conductive plug, wherein the conductive plug is a composite structure including both a primary conductor and a barrier material.

21. The method of forming a FeRAM device according to claim 20, wherein forming the conductive plug further comprises:
forming openings through the third interlayer insulating layer to expose portions of an upper surface of the upper electrode;
depositing a layer of the primary conductor to a thickness sufficient to fill the openings;
removing an upper portion of the primary conductor to expose an upper surface of the third interlayer insulating layer and form a planarized surface, thereby forming a primary conductor pattern of plugs;
removing an upper portion of the primary conductor pattern to form recessed regions;
depositing a layer of the barrier material sufficient to fill the recessed regions; and
removing an upper portion of the barrier material to expose the upper surface of the third interlayer insulating layer to form the composite conductive plugs.

22. The method of forming a FeRAM device according to claim 20, wherein forming the conductive plug further comprises:
forming openings through the third interlayer insulating layer to expose portions of an upper surface of the upper electrode;
depositing a layer of the barrier material sufficient to fill the openings; and
removing an upper portion of the barrier material to expose the upper surface of the third interlayer insulating layer to form a planarized surface and to form a barrier material pattern;
removing an upper portion of the barrier material pattern to form recessed regions;
depositing a layer of the primary conductor to a thickness sufficient to fill the recessed regions;
removing an upper portion of the primary conductor to expose an upper surface of the third interlayer insulating layer and form a planarized surface, thereby forming the composite conductive plugs.

23. The method of forming a FeRAM device according to claim 20, wherein forming the conductive plug further comprises:
forming openings through the third interlayer insulating layer to expose portions of an upper surface of the upper electrode;
depositing a conformal layer of the barrier material sufficient to form a layer of barrier material on surfaces exposed in the openings to form reduced diameter openings; and
depositing a layer of the primary conductor to a thickness sufficient to fill the reduced diameter openings;
removing upper portions of the barrier material and the primary conductor to expose an upper surface of the third interlayer insulating layer and form a planarized surface, thereby forming the composite conductive plugs.

24. A method of forming a FeRAM device comprising:
forming an array of transistors in a semiconductor substrate;
forming a first interlayer insulating layer over the transistors;
forming a bit line in the interlayer insulating layer above the transistor array and electrically connected to a source region associated with a first transistor;
forming a second interlayer insulating layer;
forming a ferroelectric structure on the second interlayer insulating layer above the bit line, wherein the ferroelectric structure includes a lower electrode, an upper electrode and a ferroelectric material provided between the lower and upper electrodes and further wherein the ferroelectric structure is electrically connected to a drain region associated with the first transistor;
forming a third interlayer insulating layer;
forming conductive plugs through the third interlayer insulating layer to contact the upper electrode;
forming a barrier layer on the surface of the third interlayer insulating layer;
forming a primary conductor layer on the surface of the barrier layer; and
forming a plate pattern and etching the primary conductor layer and the barrier layer to form a conductive plate pattern on the third interlayer insulating layer, wherein the conductive plate is directly connected to the upper electrode through the barrier material and the conductive plug.
